(19) United States
(12) Patent Application Publication
(10) Pub. No.: US 2019/0088726 A1
(43) Pub. Date: Mar. 21, 2019

(54) ORGANIC LIGHT-EMITTING DIODE (OLED) DISPLAY PANEL AND MANUFACTURING METHOD THEREOF, AND DISPLAY DEVICE

(71) Applicant: BOE TECHNOLOGY GROUP CO., LTD., Beijing (CN)

(72) Inventor: Can ZHANG, Beijing (CN)

(73) Assignee: BOE TECHNOLOGY GROUP CO., LTD., Beijing (CN)

(21) Appl. No.: 15/742,350

(22) PCT Filed: Jun. 28, 2017
(86) PCT No.: PCT/CN2017/090529

§ 371 Date: Jan. 5, 2018

(30) Foreign Application Priority Data
Dec. 23, 2016 (CN) 201611208527.9

(51) Int. Cl. H01L 27/32; H01L 51/52; H01L 51/56

(52) U.S. Cl. CPC H01L 27/3246; H01L 51/5284; H01L 2227/323; H01L 51/56; H01L 51/5221

(57) ABSTRACT

An organic light-emitting diode (OLED) display panel, a manufacturing method thereof and a display device are provided. The OLED display panel includes: a base substrate; and a pixel define layer (PDL) and a first electrode provided on the base substrate. The PDL includes at least one opening region corresponding to subpixels of the OLED display panel and a pixel spacer around the opening region; and a metal layer is provided on the pixel spacer and electrically connected with the first electrode. The metal layer is electrically connected with the first electrode.

### TECHNICAL FIELD

The present disclosure relates to an organic light-emitting diode (OLED) display panel and a manufacturing method thereof, and a display device.

### BACKGROUND

OLED display devices have gradually dominate the display field due to superior performances of low power consumption, high color saturation, wide viewing angle, low thickness and capability of realizing flexibility.

The OLED display technology has relatively mature application in active-matrix OLED (AMOLED) phone screens. For instance, as shown in FIG. 1a, which illustrates a top emission mode pixel structure, as the thickness of a cathode 01 in the top emission mode is small and is generally 10-30 nm, the resistance of the cathode is large, and the square resistance of the cathode is, for instance, 30-50Ω/□. In a case of large size of the phone screen, the IR drop problem is particularly significant and will result in current difference at different regions, so the problem of uneven display will occur in the display process. As shown in FIG. 1a, 02 refers to a base substrate; 03 refers to a pixel drive circuit (array) structural layer; 04 refers to an anode; 05 refers to a pixel define layer (PDL); and 06 refers to an organic function layer.

In addition, in the AMOLED top emission mode, RGB pixels emit light towards two sides, so the reactive power consumption will be produced, and the display quality of OLEDs can be affected. As shown in FIG. 1b, when light of red light emitting regions is scattered into blue or green light emitting regions, the crosstalk phenomenon of the emission of RGB pixels will be presented, and the display quality of the OLEDs will also be affected.

### SUMMARY

Embodiments of the present disclosure provide an OLED display panel and a manufacturing method thereof, and a display device. The OLED display panel can reduce the IR drop and improve the display effect of OLEDs.

At least one embodiment of the present disclosure provides an organic light-emitting diode (OLED) display panel, comprising: a base substrate; and a pixel define layer (PDL) and a first electrode provided on the base substrate. The PDL includes at least one opening region corresponding to subpixels of the OLED display panel and a pixel spacer around the opening region, a metal layer being provided on the pixel spacer and electrically connected with the first electrode.

In the OLED display panel provided by at least one embodiment of the present disclosure, for instance, the metal layer is provided on the first electrode and directly contact the first electrode.

The OLED display panel provided by at least one embodiment of the present disclosure may further comprise: a light absorption layer provided on the metal layer.

In the OLED display panel provided by at least one embodiment of the present disclosure, for instance, the metal layer is provided between every two adjacent subpixels.

In the OLED display panel provided by at least one embodiment of the present disclosure, for instance, the metal layer has a thickness in a range of 1,000-3,000 Å.

In the OLED display panel provided by at least one embodiment of the present disclosure, for instance, the metal layer is a continuous strip structure or a sectional strip structure.

In the OLED display panel provided by at least one embodiment of the present disclosure, for instance, the light absorption layer has a thickness in a range of 500-1,000 Å.

In the OLED display panel provided by at least one embodiment of the present disclosure, for instance, the light absorption layer include a material of silicon nitride.

In the OLED display panel provided by at least one embodiment of the present disclosure, for instance, the first electrode is a cathode of the OLED display panel.

At least one embodiment of the present disclosure also provides a method for manufacturing an organic light-emitting diode (OLED) display panel, comprising: providing a base substrate; forming a pixel define layer (PDL) and a first electrode on the base substrate, in which the PDL includes at least one opening region corresponding to subpixels of the OLED display panel and a pixel spacer around the opening region; and forming a metal layer electrically connected with the first electrode on the pixel spacer.

In the manufacturing method provided by at least one embodiment of the present disclosure, for instance, the first electrode is formed on the base substrate by an evaporation process.

In the manufacturing method provided by at least one embodiment of the present disclosure, for instance, the forming of the metal layer electrically connected with the first electrode on the pixel spacer includes: forming the metal layer on the pixel spacer by a coating process.

After forming the metal layer electrically connected with the first electrode on the pixel spacer, the manufacturing method provided by at least one embodiment of the present disclosure may further comprise: forming a light absorption layer on the metal layer by a sputtering process or a chemical vapor deposition (CVD) process.

At least one embodiment of the present disclosure also provides a display device, which comprises any of the OLED display panels.

### BRIEF DESCRIPTION OF THE DRAWINGS

In order to demonstrate clearly technical solutions of the embodiments of the present disclosure, the accompanying drawings in relevant embodiments of the present disclosure will be introduced briefly. It is apparent that the drawings may only relate to some embodiments of the disclosure and not intended to limit the present disclosure.

FIG. 1a is a schematically structural cross-section view of an OLED display panel;

FIG. 1b is a schematic diagram illustrating the crosstalk phenomenon of the OLED display panel;

FIG. 2a is a top view of an OLED display panel provided by an embodiment of the present disclosure;

FIG. 2b is a schematically structural sectional view of FIG. 2a along the A-A′ direction;

FIG. 3 is a top view of another OLED display panel provided by an embodiment of the present disclosure;

FIG. 4 is a schematic diagram illustrating the case that a metal layer reflects light in an embodiment of the present disclosure;

FIG. 5 is a schematically structural sectional view of an OLED display panel provided by an embodiment of the present disclosure;

FIG. 6 is a schematic diagram illustrating the case that a light absorption layer absorbs light in an embodiment of the present disclosure;

FIG. 7 is a top view of another OLED display panel provided by an embodiment of the present disclosure;

FIG. 8 is a flow diagram of a method for manufacturing an OLED display panel, provided by an embodiment of the present disclosure;

FIG. 9 is a flow diagram of another method for manufacturing an OLED display panel, provided by an embodiment of the present disclosure; and

FIGS. 10a-10d are respectively schematically structural sectional views of products obtained after each step of the method for manufacturing the OLED display panel, provided by an embodiment of the present disclosure.

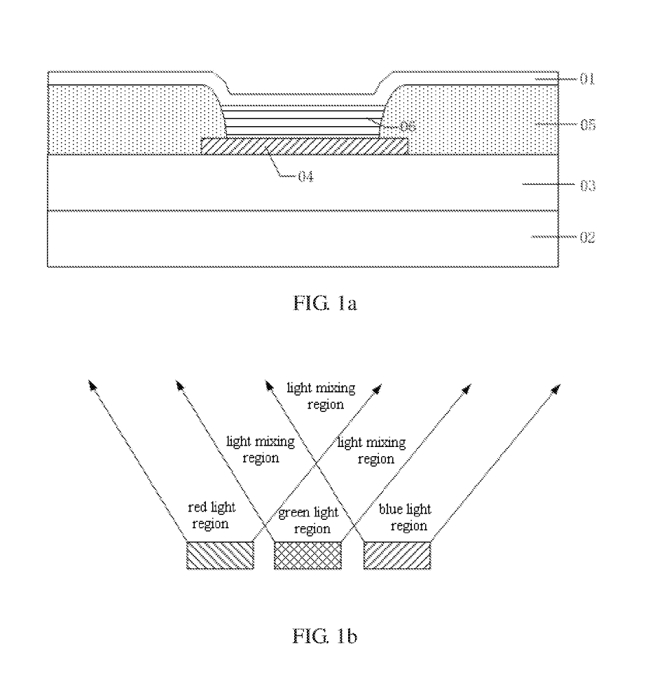

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is apparent that the described embodiments are just a part but not all of the embodiments of the disclosure. Based on the described embodiments herein, those skilled in the art can obtain other embodiment(s), without any creative work, which shall be within the scope of the disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present disclosure, are not intended to indicate any sequence, amount or importance, but for distinguishing various components. The terms, such as “comprise/comprising,” “include/including,” or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not limited to a physical connection or mechanical connection, but may include an electrical connection/coupling, directly or indirectly. The terms, “on,” “under,” “left,” “right,” or the like are only used to indicate relative position relationship, and when the position of the object which is described is changed, the relative position relationship may be changed accordingly.

Detailed description will be given below to an organic light-emitting diode (OLED) display panel, and a manufacturing method thereof, and a display device, provided by embodiments of the present disclosure, with reference to the accompanying drawings.

In the OLED display panel provided by embodiments of the present disclosure, the size of patterns is generally in microns or less. For clarity, the size of structures in the accompanying drawings of the embodiments of the present disclosure is enlarged and does not represent the actual size and scale unless otherwise specified.

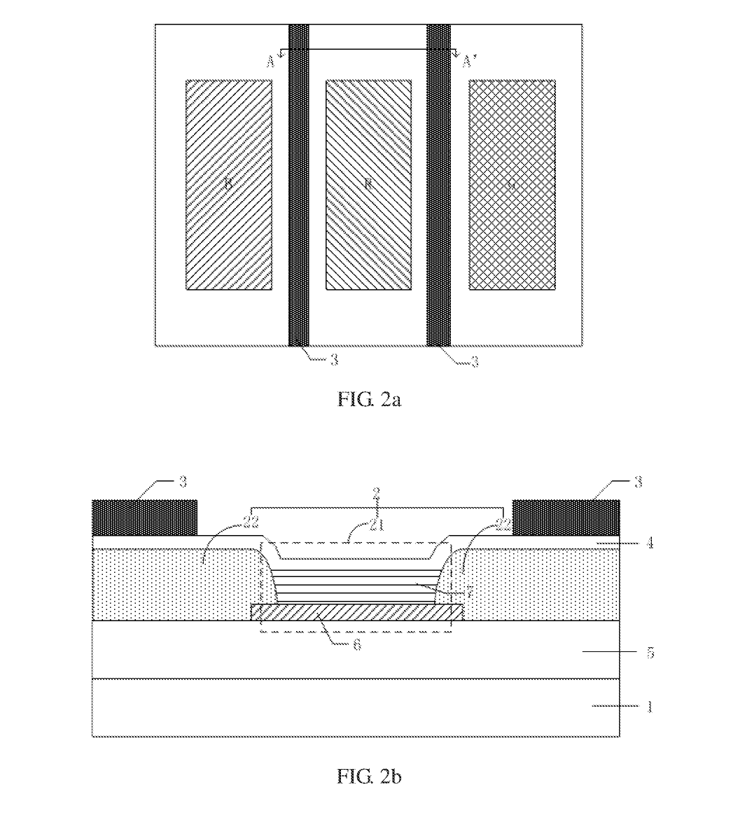

For instance, at least one embodiment of the present disclosure provides an OLED display panel. As illustrated in FIGS. 2a and 2b, the OLED display panel comprises: a base substrate 1 and a pixel define layer (PDL) 2 and a first electrode 4 (e.g., a cathode) disposed on the base substrate 1. The PDL 2 includes at least one opening region corresponding to subpixels of the OLED display panel and a pixel spacer 2 disposed around the opening region. A metal layer 3 is disposed on the pixel spacer 22 and electrically connected with the first electrode 4.

It should be noted that 5 refers to a pixel drive circuit (array) structural layer; 6 refers to a second electrode (e.g., anode) of the OLED display panel; and 7 refers to an organic function layer of the OLED display panel. For instance, the organic function layer includes a hole injection layer (HIL), a hole transport layer (HTL), an emission layer (EML), an electron transport layer (ETL), an electron blocking layer (EBL), or the like.

The cathode of the OLED display panel is generally made of thin and transparent metallic materials, such as aluminum and magnesium metal. The resistance of the cathode made of the above materials is large. The resistance of the cathode can be reduced by connecting metal layers in parallel. It should be noted that the resistance of the anode can also be reduced by connecting metal layers in parallel. Description will be given below exemplarily in an instance that the cathode is electrically connected with the metal layer to reduce the resistance of the cathode.

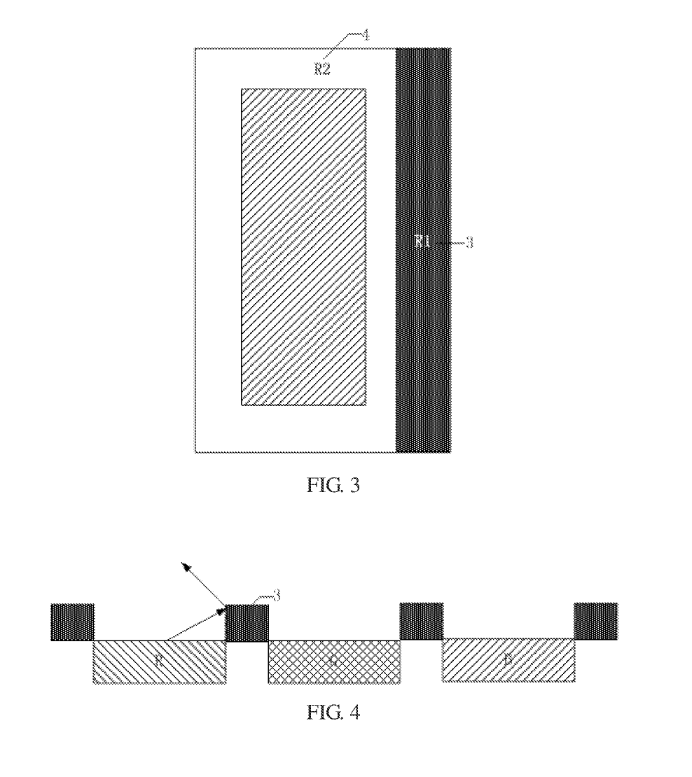

In the OLED display panel provided by the embodiment of the present disclosure, as shown in FIG. 3, for a single pixel, for example, the metal layer 3 is disposed on the pixel spacer and electrically connected with the first electrode 4 (e.g., the cathode). Supposing the resistance of the metal layer 3 is R₁ and the resistance of the cathode 4 is R₂, it is equivalent that R₁ and R₂ are connected with each other in parallel, the resistance R₃ after parallel connection is obtained, namely R₃=1/(1/R₁+1/R₂)<R₁, so the resistance R₃ obtained after parallel connection of the metal layer 3 and the cathode 4 is reduced compared to the resistance R₂ of the cathode 4. In this way, the IR drop can be improved. Meanwhile, as shown in FIG. 4, as the metal layer 3 has a high reflectivity, light emitted by the subpixels will be reflected to the outside through the side of the metal layer, so light mixing regions can be reduced. In this way, the crosstalk on the emission of adjacent subpixels in the process of subpixel emission can be improved, so the reactive power consumption can be reduced, and the display effect of OLEDs can be improved.

For instance, in the OLED display panel provided by the embodiment of the present disclosure, in order to electrically connect the metal layer and the cathode, as shown in FIG. 2b, the metal layer is disposed on the cathode and directly contacts the cathode, so the resistance after parallel connection can be reduced. In this way, the IR drop can be reduced, and the problem of uneven display in the display process due to large IR drop will not occur.

It should be noted that the cathode may also be disposed on the metal layer and directly contacts the metal layer, and the metal layer is directly disposed on the pixel spacer. This will also allow the resistance after parallel connection to be reduced and improve the problem of IR drop, so as to avoid the problem of uneven display in the display process due to large IR drop.

For instance, when the first electrode 4 receives a voltage signal and transmits the voltage signal and the voltage signal arrives at the metal layer 3 electrically connected with the first electrode 4, the metal layer 3, as a transmission branch of the voltage signal, simultaneously transmits the voltage signal with the first electrode 4, which is equivalent to the first electrode 4 and the metal layer 3 forming a parallel circuit to reduce the resistance in the transmission process of the electrical signal; or the metal layer 3 may receive the voltage signal at first, and when the voltage signal arrives at the first electrode 4 electrically connected with the metal layer 3, the first electrode 4, as a transmission branch of the voltage signal, simultaneously transmits the voltage signal with the metal layer 3; or the first electrode 4 and the metal layer 3 simultaneously receive the voltage signal and simultaneously transmit the voltage signal as two branches.

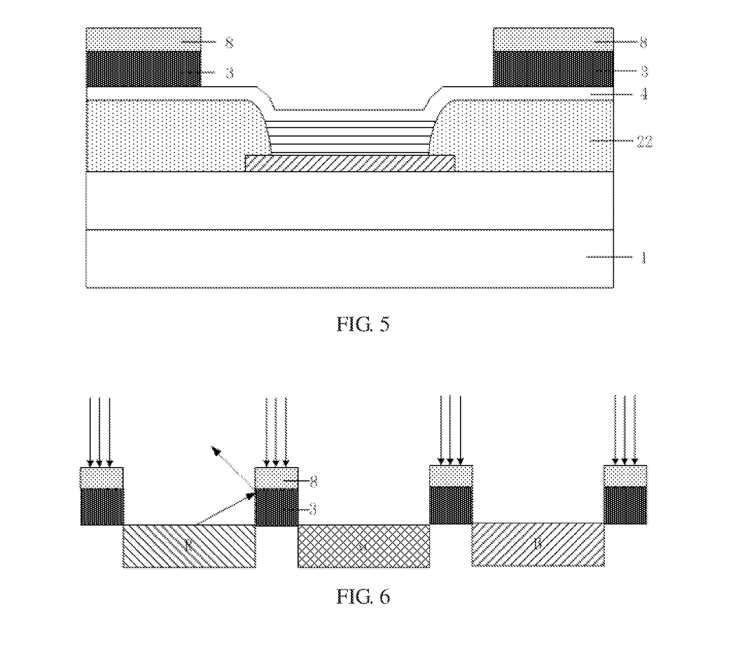

For instance, as shown in FIG. 5, the OLED display panel may also comprise: a light absorption layer 8 disposed on the metal layer 3. Due to the function of the light absorption layer 8, as shown in FIG. 6, partial light incident from the outside to the inside of an electroluminescent structure will be absorbed by the light absorption layer 8 and cannot be emitted to the surface of the electroluminescent structure, so the display effect of the OLEDs can be further improved.

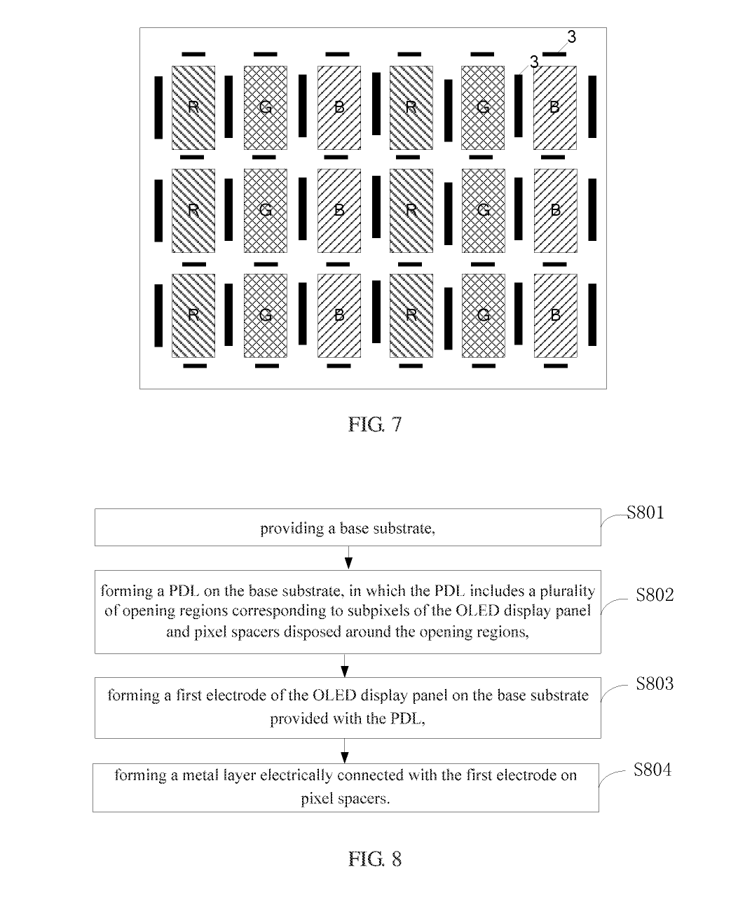

For instance, in order to further reduce the reactive power consumption of the emission of RGB pixels towards two sides and avoid the crosstalk phenomenon of the emission of the RGB pixels, as shown in FIG. 7, the metal layer 3 may be disposed between every two adjacent subpixels, meanwhile, the light absorption layer 8 (not shown in the figure) may be disposed on each metal layer 3.

For instance, in the OLED display panel provided by the embodiment of the present disclosure, for the side of the metal layer to be able to effectively reflect light emitted between two adjacent subpixels, the thickness of the metal layer may be 1,000-3,000 Å, e.g., 1,000 Å, 2,000 Å, or 3,000 Å. The thickness of the metal layer may be determined according to actual conditions. No limitation will be given here.

For instance, in the OLED display panel provided by the embodiment of the present disclosure, in order to simplify the manufacturing process, the metal layer may be a continuous strip structure or a sectional strip structure. The structure of the metal layer may be determined according to actual conditions. No limitation will be given here.

For instance, in the OLED display panel provided by the embodiment of the present disclosure, when the metal layer is a strip structure, the width of the metal layer may be 2 μm-20 μm, e.g., 2 μm, 6 μm, 10 μm, 14 μm, 16 μm, 18 μm, or 20 μm. For a 5.0 inch high-definition display (1280*720), for example, the pixel size is 81 μm*81 μm, the pitch value between pixel emission regions is 30 μm, in this case, the width of the metal layer may be 7 μm. The width of the metal layer may be determined according to actual conditions. No limitation will be given here.

For instance, in the OLED display panel provided by the embodiment of the present disclosure, the material of the metal layer may be any one selected from the group consisting of silver, aluminum, copper, gold and platinum or a combination thereof. Metallic materials with high reflectivity and low resistance are selected. No limitation will be given here.

For instance, in the OLED display panel provided by the embodiment of the present disclosure, for the light absorption layer to be able to effectively absorb partial light incident from the outside, the thickness of the light absorption layer may be 500-1,000 Å, e.g., 500 Å, 600 Å, 700 Å, 800 Å, 900 Å, or 1000 Å. The thickness of the light absorption layer may be determined according to actual conditions. No limitation will be given here.

For instance, in the OLED display panel provided by the embodiment of the present disclosure, the material of the light absorption layer may be silicon nitride. The material of the light absorption layer may select materials with high extinction coefficient. No limitation will be given here.

For instance, other layer structures, such as a hole blocking layer and a cathode protective layer may also be arranged in the OLED display panel provided by the embodiment of the present disclosure. Structures, such as thin-film transistors (TFTs), gate lines and data lines are also disposed on the base substrate. These structures may have a variety of implementations. No limitation will be given here.

For instance, at least one embodiment of the present disclosure also provides a method for manufacturing the OLED display panel. The principle of solving problems of the method is similar to that of the OLED display panel, so the embodiments of the method may refer to the embodiments of the OLED display panel. No further description will be given to duplicate details.

For instance, as shown in FIG. 8, the method for manufacturing the OLED display panel provided by an embodiment of the present disclosure comprises the following steps.

S801: providing a base substrate.

S802: forming a PDL on the base substrate, in which the PDL includes a plurality of opening regions corresponding to subpixels of the OLED display panel and pixel spacers disposed around the opening regions;

S803: forming a first electrode of the OLED display panel on the base substrate provided with the PDL.

S804: forming a metal layer electrically connected with the first electrode on pixel spacers.

For instance, in the method for manufacturing the OLED display panel provided by an embodiment of the present disclosure, the forming of the first electrode on the base substrate provided with PDL patterns in the step S803 may be implemented by the following way: forming the first electrode (e.g., cathodes) on the base substrate provided with the PDL by an evaporation process.

It should be noted that patterns of organic function layers of the OLED display panel, such as an HIL, an HTL, an EML, an ETL and an EBL are formed by an evaporation process via a fine metal mask (FMM) or a metal mask (open mask). To enable the connection between the cathode and the metal layer to be formed, the cathode is formed by an evaporation process via a metal mask (open mask).

For instance, in the method for manufacturing the OLED display panel provided by at least one embodiment of the present disclosure, the forming of the metal layers electrically connected with the first electrode on the pixel spacers in the step S804 may adopt the following way: forming the metal layers electrically connected with the first electrode on the pixel spacers by a coating process.

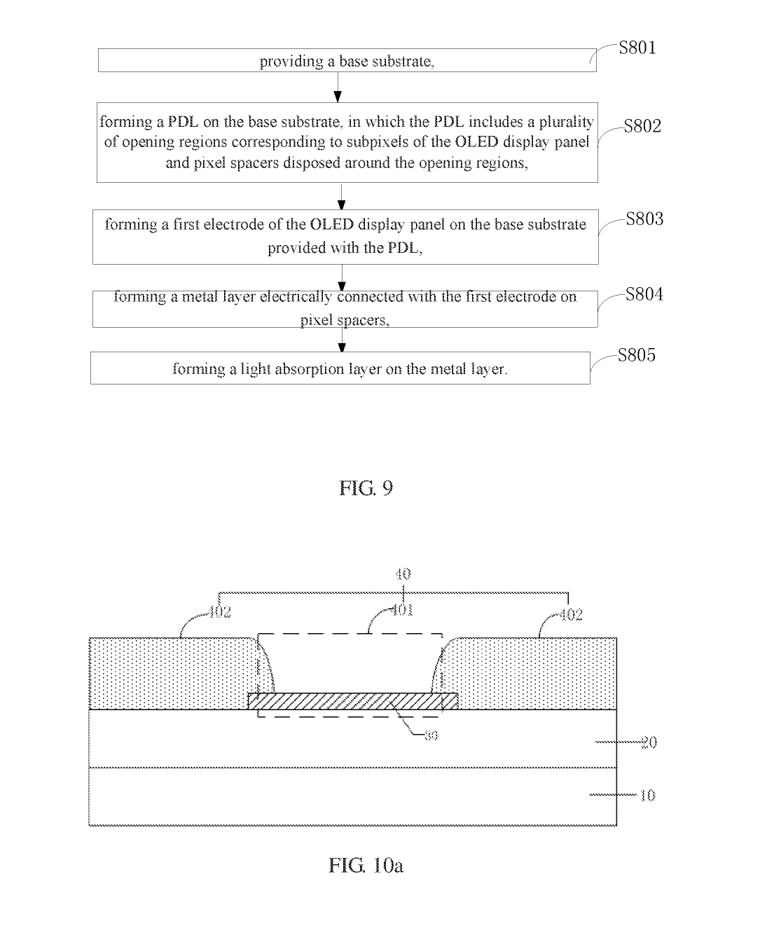

For instance, as shown in FIG. 9, after forming the metal layers electrically connected with the first electrode on the pixel spacers in the step S804, the method for manufacturing the OLED display panel provided by the embodiment of the present disclosure may further comprise the following step:

S805: forming light absorption layers on the metal layers.

For instance, in the method for manufacturing the OLED display panel provided by at least one embodiment of the present disclosure, the forming of the light absorption layers on the metal layers in the step S805 may adopt the following way: forming the light absorption layers on the metal layers by a sputtering process, or a CVD process.

For instance, for the first electrode being a cathode, for example, the steps of manufacturing the OLED display panel are as follows:

S1: providing a base substrate.

For instance, the base substrate may be a transparent glass substrate, or a transparent plastic substrate.

S2: forming a PDL on the base substrate, in which the PDL includes a plurality of opening regions corresponding to subpixels of the OLED display panel and pixel spacers disposed around the opening regions.

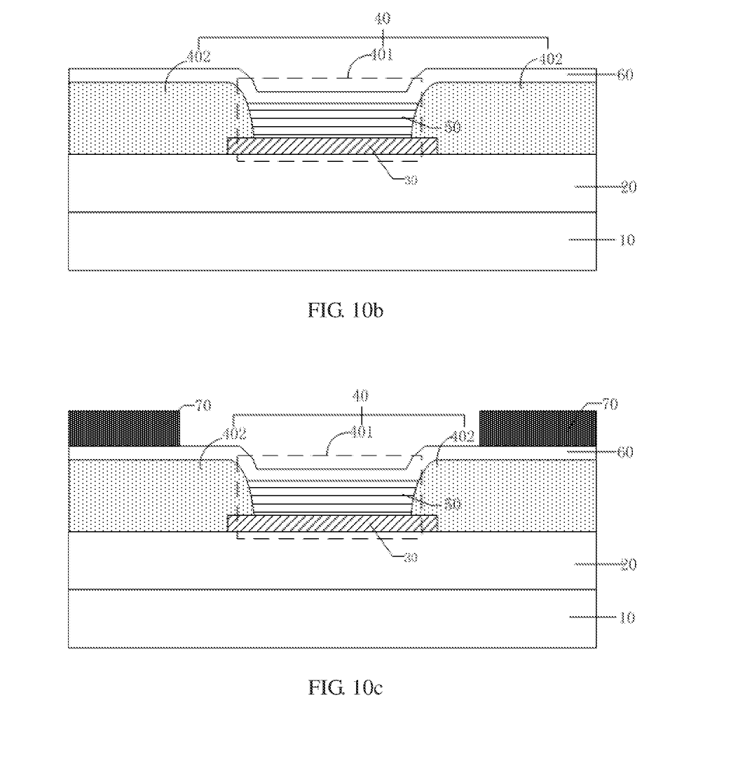

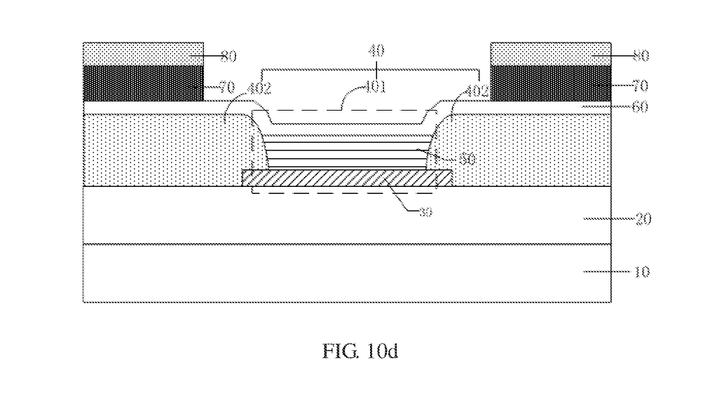

As shown in FIG. 10a, firstly, a pixel drive circuit (array) structural layer 20 is formed on a base substrate 10; secondly, a pattern of anode 30 is formed on the pixel drive circuit (array) structural layer 20; and thirdly, a PDL 40 is formed on the base substrate 10 provided with the anode 30. The PDL 40 includes a plurality of opening regions 401 corresponding to subpixels of the OLED display panel and pixel spacers 402 disposed around the opening regions 401.

S3: forming a cathode of the OLED display panel on the base substrate provided with the PDL.

As shown in FIG. 10b, firstly, organic function layers 50 are formed in the opening regions 401 of the PDL 40 by an evaporation process via an FMM; and secondly, a cathode 60 is formed on the base substrate 10 provided with the organic function layers 50 by an evaporation process via an open mask. The cathode 60 covers the entire PDL 40.

For instance, the organic function layers include an HIL, an HTL, an EML, an ETL, an EBL, etc.

S4: forming a metal layer electrically connected with the cathode on pixel spacers.

As shown in FIG. 10c, a metal layer is formed on the pixel spacers 402 by a coating process (e.g., a sputtering process), and subsequently, the metal layer 70 is formed by an etching process. The metal layer 70 is electrically connected with the cathode 60. In this case, a pattern of the metal layer 70 is a strip structure. The metal layer 70 is disposed on the cathode 60 and directly contacts the cathode 60.

S5: forming a light absorption layer on the metal layer.

As shown in FIG. 10d, the light absorption layer 80 is formed on the metal layer 70 by a sputtering process or a CVD process.

The OLED display panel provided by the embodiment of the present disclosure is manufactured by the steps S1 to S5.

At least one embodiment of the present disclosure also provides a display device, which comprises the OLED display panel provided by the embodiment of the present disclosure. The display device may be any product or component with display function, such as a mobile phone, a tablet PC, a TV, a display, a notebook computer, a digital picture frame or a navigator. Other necessary components of the display device shall be understood to be included by those skilled in the art, which are not repeated herein, and shall not be construed as the limitation of the present disclosure. The embodiments of the display device may refer to the embodiments of the OLED display panel. No further description will be given here the duplicate details.

In the OLED display panel and the manufacturing method thereof, and the display device, provided by embodiments of the present disclosure, the OLED display panel comprises: a base substrate; and a PDL and a first electrode disposed on the base substrate. The PDL includes at least one opening region corresponding to subpixels of the OLED display panel and a pixel spacer around the opening region. A metal layer is disposed on the pixel spacer and electrically connected with the first electrode. As the metal layer is disposed on the pixel spacer and electrically connected with the cathode, the resistance of the cathode can be reduced, so the IR drop can be reduced. Meanwhile, due to the reflection function of the metal layer, the crosstalk on the emission of adjacent pixels in the process of pixel emission can be avoided, so that the display effect of OLEDs can be improved.

The described above are only specific embodiments of the present disclosure, and the present disclosure is not limited thereto. The scope of the present disclosure is defined by the claims.

The present application claims priority of the Chinese patent application No. 201611208527.9, filed on Dec. 23, 2016, the disclosure of which is incorporated herein by reference as part of the application.

1: An organic light-emitting diode (OLED) display panel, comprising:
a base substrate; and
a pixel define layer (PDL) and a first electrode provided on the base substrate, wherein
the PDL includes at least one opening region corresponding to subpixels of the OLED display panel and a pixel spacer around the opening region, a metal layer being provided on the pixel spacer and electrically connected with the first electrode.

2: The OLED display panel according to claim 1, wherein the metal layer is provided on the first electrode and directly contact the first electrode.

3: The OLED display panel according to claim 2, further comprising: a light absorption layer provided on the metal layer.

4: The OLED display panel according to claim 1, wherein the metal layer is provided between every two adjacent subpixels.

5: The OLED display panel according to claim 4, wherein the metal layer has a thickness in a range of 1,000-3,000 Å.

6: The OLED display panel according to claim 5, wherein the metal layer is a continuous strip structure or a sectional strip structure.

7: The OLED display panel according to claim 3, wherein the light absorption layer has a thickness in a range of 500-1,000 Å.

8: The OLED display panel according to claim 7, wherein the light absorption layer include a material of silicon nitride.

9: The OLED display panel according to claim 1, wherein the first electrode is a cathode of the OLED display panel.

10: A method for manufacturing an organic light-emitting diode (OLED) display panel, comprising:
providing a base substrate;
forming a pixel define layer (PDL) and a first electrode on the base substrate, in which the PDL includes at least one opening region corresponding to subpixels of the OLED display panel and a pixel spacer around the opening region; and
forming a metal layer electrically connected with the first electrode on the pixel spacer.

11: The manufacturing method according to claim 10, wherein the first electrode is formed on the base substrate by an evaporation process.

12: The manufacturing method according to claim 10, wherein the forming of the metal layer electrically connected with the first electrode on the pixel spacer includes:
forming the metal layer on the pixel spacer by a coating process.

13: The manufacturing method according to claim 12, after forming the metal layer electrically connected with the first electrode on the pixel spacer, it further comprises:
forming a light absorption layer on the metal layer by a sputtering process or a chemical vapor deposition (CVD) process.

14: A display device, comprising the OLED display panel according to claim 1.

15: The OLED display panel according to claim 2, wherein the metal layer is provided between every two adjacent subpixels.

16: The OLED display panel according to claim 3, wherein the metal layer is provided between every two adjacent subpixels.

17: The OLED display panel according to claim 15, wherein the metal layer has a thickness in a range of 1,000-3,000 Å.

18: The OLED display panel according to claim 17, wherein the metal layer is a continuous strip structure or a sectional strip structure.

19: The OLED display panel according to claim 18, wherein the first electrode is a cathode of the OLED display panel.
